(19) United States
(12) Patent Application Publication
(10) Pub. No.: US 2007/0267759 A1
(43) Pub. Date: Nov. 22, 2007

(54) Semiconductor device with a distributed plating pattern

(76) Inventors: Chih-Chin Liao, Yuanlin (TW); Han-Shiao Chen, Da-an Township (TW); Chin-Tien Chiu, Taichung City (TW); Cheemen Yu, Madison, WI (US); Hem Takiar, Fremont, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/435,518

(22) Filed: May 17, 2006

(51) Int. Cl. H01L 23/48

(52) U.S. Cl. 257/786

(57) ABSTRACT

A substrate, and a semiconductor die package formed therefrom, are disclosed which include a distributed plating pattern for reducing mechanical stress on the semiconductor die. The substrate according to embodiments of the invention may include traces and contact pads plated in a double image plating process. Additionally, the substrate may include dummy plating areas including plating material. The plated vias and/or traces and the plating material within the dummy plating areas provide a plating pattern which is evenly distributed across the surface of the substrate. The even distribution of the plating pattern prevents peaks and valleys in the finished substrate.

### CROSS REFERENCE TO RELATED APPLICATION

This application is related to United States Patent Application entitled “METHOD OF REDUCING STRESS ON A SEMICONDUCTOR DIE WITH A DISTRIBUTED PLATING PATTERN”, Inventors Chih-Chin Liao, Han-Shiao Chen, Chin-Tien Chiu, Cheemen Yu, Hem Takiar, filed on the same day as the present application and incorporated herein by reference in its entirety.

### BACKGROUND OF THE INVENTION

1. Field of the Invention

Embodiments of the present invention relate to a substrate, and a semiconductor die package formed therefrom, including a distributed plating pattern for reducing mechanical stress on the semiconductor die.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While a wide variety of packaging configurations are known, flash memory storage cards may in general be fabricated as system-in-a-package (SiP) or multichip modules (MCM), where a plurality of die are mounted on a substrate. Prior art FIG. 1 is a top view of a substrate 20 with an outline of one or more semiconductor die 22 mounted thereon. Referring to FIG. 1 and the cross-sectional view of the substrate and die shown in prior art FIG. 2, the substrate 20 may in general include a dielectric core 24 having a conductance pattern of electrical traces 26 defined on one or both sides. Through-holes, or vias, 28 are formed through the substrate, and plated to allow electrical communication between the conductance patterns on the top and bottom surfaces of the substrate. Contact pads 30 are additionally defined in the conductance patterns to which the die and other electronic components may be wire bonded and/or surface mounted as by soldering.

The copper of the conductance patterns provides a poor bonding surface for soldering the die and other electronic components to the contact pads 30. It is therefore known to plate the contact pads with, for example, gold or nickel/gold (Ni/Au) plating, to which the die and components may be suitably soldered. A common plating technique is to provide a plating bus and plating tails which short together all of the contact pads 30 and areas to be plated. An electroplating process may then be performed where the substrate is immersed in an aqueous solution containing ions of the plating material. A current is provided to all shorted contact pads, which current attracts the metal ions to plate the contact pads to a desired thickness.

While an efficient method for plating electrical contacts on substrates, electroplating has drawbacks. First, the electrical connections between all contacts often are not severed until package singulation, making it impossible to electrically test the trace pattern in the substrate before connecting the die thereto. Moreover, the large area of the plating tails takes up valuable real estate on the substrate, and also may create noise due to the antenna effect.

It is therefore known to plate substrates in other processes (referred to as busless processes) which do not use busses to short together areas to be plated. One popular busless plating process is double image processing. Double image processing starts with a substrate having a core and solid (unpatterned) conducting layers formed on the core. A Ni/Au plating layer is patterned on the surface of the solid conducting layer(s) in a known imaging process such as photolithography. Thereafter, portions of the conducting layers are etched away to define the electrical traces and conductance patterns in the conducting layers in a second known imaging process, again, such as photolithography. In the second imaging process, photoresist is applied to certain areas of the conducting layers, and thereafter, those areas not covered by either photoresist or the Ni/Au plating are etched away.

The resulting patterned substrate is then typically laminated in solder mask 32, as shown in FIG. 2, to cover all areas other than the contact pads 30 to which wires and surface mounted components are to be soldered. Die 22 and other components may then be affixed to the substrate and electrically connected. Once electrical connections between the die and substrate are made, the assembly is then typically encased in a molding compound in a transfer molding process to provide a protective package.

During the transfer molding process, the molding machine may output an injection force typically about 0.8 tons to drive the molding compound into the mold cavity and around the surface mounted components. A problem with conventional substrates formed by double image processing is that the surface of the substrate is not flat. In particular, as described above, the traces 26 and vias 28 are plated. As shown in the cross-sectional view of FIG. 2, those plated areas have a higher profile than the surrounding areas without plating. Thus, when the substrate is laminated with solder mask, peaks form at the plated areas and valleys form between the plated areas. With the high pressure of the transfer molding process, the molding compound above the die 22 generates large forces down on the top of the die (indicated by arrows A). For die packages having a footprint of about 4.5 mm by 2.5 mm, the forces down on the top of die 22 may be on the order of about 1.2 kgf/mm2. As there is a void beneath the die due to the peaks and valleys in the solder mask, these forces generate large stresses within the die 22.

In the past, the die were better able to withstand these stresses generated during the transfer molding process. However, the constant drive toward smaller form factor packages require very thin die. It is presently known to employ wafer backgrind during the semiconductor fabrication process to thin die to a range of about 2 mils to 13 mils. At these thicknesses, the die are often not able to withstand the stresses generated during the molding process and they may crack. Die cracking under the stress of the molding process will generally result in the package having to be discarded. Occurring at the end of the semiconductor fabrication and packaging process, this is an especially costly and burdensome problem.

### SUMMARY OF THE INVENTION

Embodiments of the invention relate to a substrate, and a semiconductor die package formed therefrom, including a distributed plating pattern for reducing mechanical stress on the semiconductor die. The substrate according to embodiments of the invention may include traces and contact pads plated in a double image plating process. Additionally, the substrate may include areas, referred to herein as dummy plating areas, which also include plating.

The substrate in embodiments of the invention may be fabricated in a double image process to include vias, plated electrical traces, plated contact pads, plated contact fingers, dummy patterns and the dummy plating areas. The plating material in the dummy plating areas serves to increase the amount of plating on the surface of the substrate, thereby lessening the space between adjacent plated vias or leads found in conventional substrates. The plated vias and/or traces and the plating within the dummy plating areas provide a plating pattern which is evenly distributed across the surface of the substrate. The even distribution of the plating pattern prevents peaks and valleys in the finished substrate.

Once the double imaging process is completed, the top and bottom surfaces of the substrate may be laminated with a solder mask. Thereafter, one or more die may be mounted to the substrate. The one or more die may be electrically connected to the substrate by soldering leads of the die to the plated contact pads in a known wire bond and/or SMT mounting process. The dummy plating pattern may be applied to the surface of the substrate that receives the die. The distributed plating pattern including the plated vias/traces and the plating material in the dummy plating areas provides a flat surface of the substrate to which the die may be attached. The one or more die and at least the adjacent surface of the substrate may then be encapsulated in a molding compound to form a finished semiconductor package.

The dummy plating areas may include plating in a wide variety of configurations. In embodiments, the plating material may be applied in discrete and separate shapes, such as for example a plurality of circular or other shaped masses deposited on the substrate. In alternative embodiments, the plating material in the dummy plating areas may be applied as straight, curved or irregular shaped lengths on top of the dummy metal pattern formed on the substrate.

### BRIEF DESCRIPTION OF THE DRAWINGS

FIG. 1 is a top view of a conventional substrate with an outline of a die shown.

FIG. 2 is a cross-sectional side view through line 2-2 of FIG. 1.

FIG. 3 is a flowchart of the process steps for fabricating a substrate and semiconductor package according to embodiments of the present invention.

FIG. 4 is a cross-sectional side view of a substrate at the beginning of the process for fabricating a substrate according to embodiments of the present invention.

FIG. 5 is a cross-sectional side view of a substrate with a mask pattern defined on the substrate according to embodiments of the present invention.

FIG. 6 is a cross-sectional side view of a substrate with a mask pattern defined on the substrate and a distributed plating pattern within the spaces between the mask pattern according to embodiments of the present invention.

FIG. 7 is a cross-sectional side view of a substrate with a distributed plating pattern defined on the substrate after the mask has been removed according to embodiments of the present invention.

FIG. 8 is a cross-sectional side view of a substrate with a plating pattern and a second mask pattern applied to the substrate for patterning the electrical traces in the conducting layer according to embodiments of the present invention.

FIG. 9 is a cross-sectional side view of a substrate after the exposed portions of the conducting layer have been etched away according to embodiments of the present invention.

FIG. 10 is a top view of a substrate including a distributed plating pattern according to embodiments of the present invention.

FIG. 11 is a cross-sectional side view of a substrate through line 11-11 of FIG. 10.

FIG. 12 is a cross-sectional side view of a distributed plating pattern substrate after solder mask lamination according to embodiments of the present invention.

FIG. 13 is a top view of a substrate including a distributed plating pattern according to embodiments of the present invention and including the outline of a semiconductor die mounted thereto.

FIG. 14 is a cross-sectional side view of a substrate through line 14-14 of FIG. 13.

FIG. 15 is a cross-sectional side view of a semiconductor package including a substrate having a distributed plating pattern according to embodiments of the present invention and a semiconductor die.

FIG. 16 is a top view of a substrate including a distributed plating pattern according to an alternative embodiment of the present invention and including the outline of a semiconductor die mounted thereto.

FIG. 17 is a cross-sectional side view of a substrate through line 17-17 of FIG. 16.

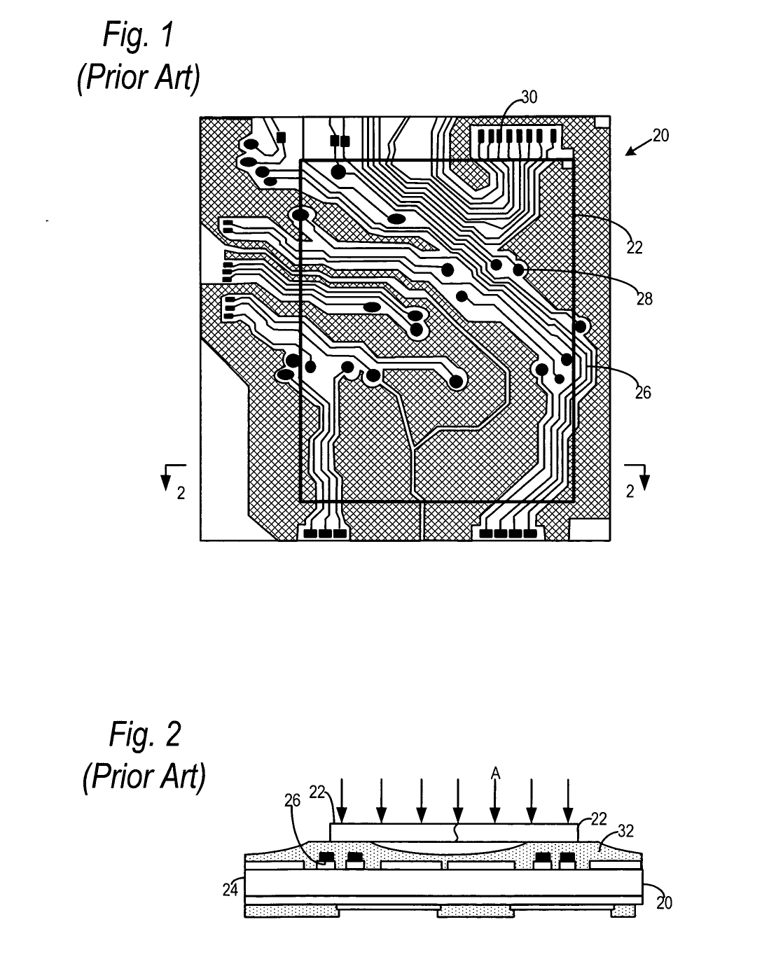

### DETAILED DESCRIPTION

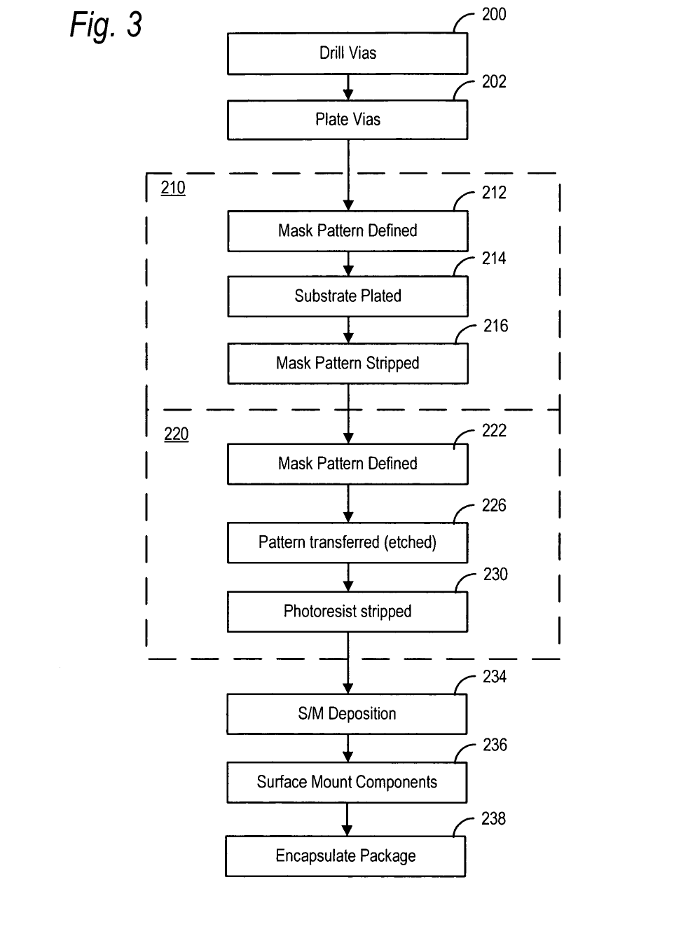

Embodiments of the invention are described with reference to FIGS. 3 through 17, which relate to a substrate, and a semiconductor die package formed therefrom, including a distributed plating pattern for reducing mechanical stress on the semiconductor die. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

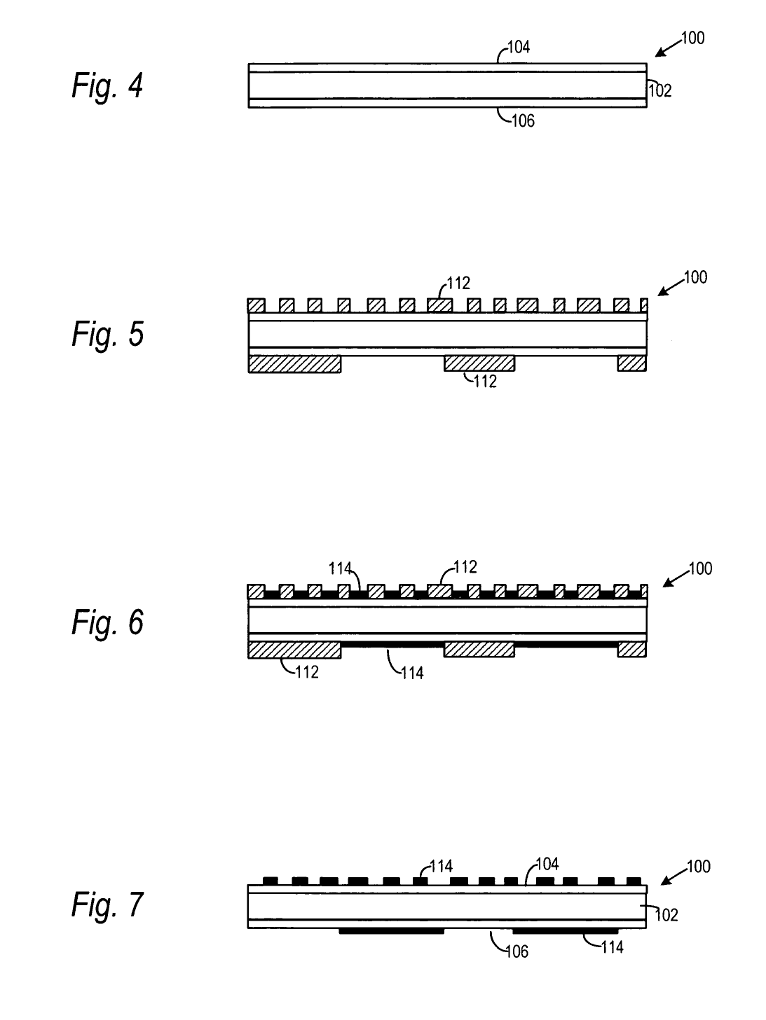

Embodiments of the present invention will now be described with reference to the flowchart of FIG. 3 and the cross-sectional side and top views of FIGS. 4 through 15. FIG. 4 shows a cross-sectional side view of a substrate 100 (prior to processing) on which a semiconductor package may be formed. Substrate 100 may be part of a substrate panel for batch processing a plurality of semiconductor packages at the same time.

Substrate 100 may be for example a printed circuit board, but it is understood that substrate 100 may be a variety of other substrates in alternative embodiments. Substrate 100 may be formed of a core 102, having a top conductive layer 104 formed on a top surface of the core 102, and a bottom conductive layer 106 formed on the bottom surface of the core 102. The core 102 may be formed of various dielectric materials such as for example, polyimide laminates, epoxy resins including FR4 and FR5, bismaleimide triazine (BT), and the like. Although not critical to the present invention, core 102 may have a thickness of between 40 microns (μm) to 200 μm, although the thickness of the core may vary outside of that range in alternative embodiments. The core 102 may be ceramic or organic in alternative embodiments.

The conductive layers 104 and 106 may be formed of copper or copper alloys, plated copper or plated copper alloys, Alloy 42 (42Fe/58Ni), copper plated steel, or other metals and materials known for use on substrates. The layers 104 and 106 may have a thickness of about 10 μm to 24 μm, although the thickness of the layers 104 and 106 may vary outside of that range in alternative embodiments.

Referring now to the flowchart of FIG. 3, the substrate 100 may be fabricated by initially drilling through-holes, or vias, 108 (FIG. 10) through the substrate in step 200, and plating the vias 108 in step 202 to allow electrical communication between the conductive layers 104 and 106. The vias 108 may be formed across the substrate 100, including at positions beneath the semiconductor die to be mounted on substrate 100 as explained hereinafter.

Areas of the substrate may then be plated in a double imaging process. The areas that are plated include electrical traces for carrying signals around the substrate, contact pads to which leads of surface mounted components may be soldered, and contact fingers for establishing electrical contact with a host device in which a semiconductor package including substrate 100 is used. Moreover, as explained below, dummy plating areas may be applied to a surface of the substrate 100 to provide a distributed pattern of plating on the substrate and to even out the surface of the substrate 100.

Substrate 100 may be plated in a busless, double imaging process including in general a first imaging process 210 for plating the substrate 100 and a second imaging process 220 for defining the traces and conductance pattern in the substrate 100. The first imaging process 210 includes the step 212 of forming a mask pattern 112 on the conductive layers 104 and 106 as shown in FIG. 5. The mask pattern 112 may be formed on the layers 104 and 106 in a known process, such as for example in a photolithography process. In such a process, a solid layer of photoresist is laminated onto the layers 104 and 106. A photomask containing the outline of the plating pattern may then be placed over the photoresist film (one photomask for each layer 104 and 106). The photoresist film may then be exposed and developed to remove the photoresist from areas on the conductive layers that are to be plated. The mask pattern 112 is the negative of the plating pattern to be deposited on the conductive layers 104 and 106.

In step 214, the exposed surfaces of layers 104 and 106 are plated with a known plating material 114 (FIG. 6), such as for example Ni/Au, though other materials are contemplated. The Ni/Au plating layer 114 may be plated in a known process, such as for example any of various thin film deposition processes. In step 216, the mask pattern layer 112 may be stripped away as shown in FIG. 7, for example in a known photoresist stripping step. The resulting structure includes core 102, solid conducting layers 104 and 106, and plating material 114. As explained in greater detail hereinafter, the plating material 114 is plated onto electrical traces for carrying electrical signals and contact pads for surface mounting components, but the plating material 114 is also plated onto the substrates in other areas in a distributed pattern to help define a flat, uniform surface of substrate 100.

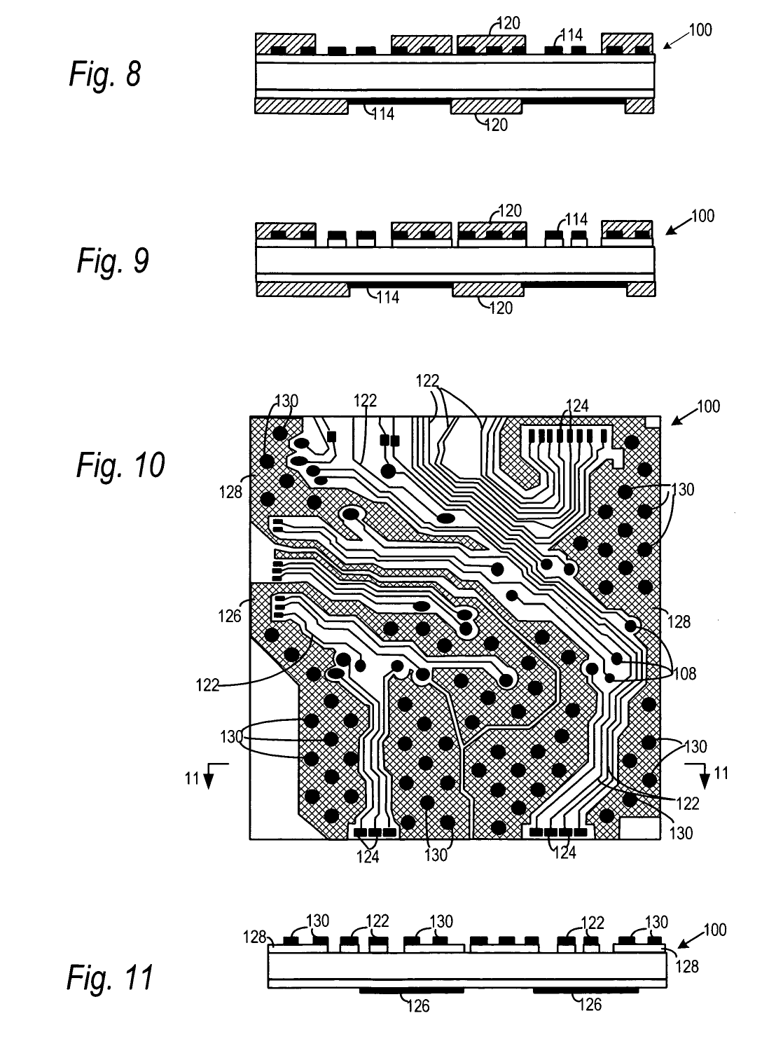

The second imaging process 220 may etch the layers 104 and 106 to define a conductance pattern in layers 104 and/or 106 including electrical traces and contact pads. One process for forming the conductance pattern on the substrate 100 includes the step 222 of forming a mask pattern 120 on the conductive layers 104 and 106 as shown in FIG. 8. The mask pattern 120 may be formed only over exposed areas of the conductive layers 104, 106 (i.e., those areas which are not plated), or the mask pattern 120 may be formed over the exposed areas and plated areas. The mask pattern 120 may be formed on the surfaces of the substrate 100 in a known process, such as for example in a photolithography process. In such a process, a solid layer of photoresist is laminated onto the surfaces of the substrate 100. A photomask containing the pattern to be defined in the respective conductive layers 104, 106 (one photomask for each layer) may then be placed over the photoresist film.

The pattern to be defined in the layers 104 and 106 includes a conductance pattern having the contact pads and electrical traces for carrying signals around the substrate 100. Moreover, it is known in the art to define a dummy pattern in the conductive layers 104 and 106 in areas not forming parts of the conductance pattern to reduce warpage of the substrate 100 after encapsulation. The dummy pattern may for example be a mesh pattern of metal defined in the conductive layers 104 and 106 (as shown for example in FIG. 10). The dummy pattern may have a variety of other configurations, such as those shown for example in U.S. patent application Ser. No. 11/171,095, entitled, “Method of Reducing Warpage In An Over-Molded IC Package,” (Case Docket No. SDK0696.000US), and in U.S. patent application Ser. No. 11/171,819 entitled “Substrate Warpage Control and Continuous Electrical Enhancement,” (Case Docket No. SDK0716.000US), both of which applications are incorporated by reference herein in their entirety.

After the photomask is applied, the mask pattern 120 may then be exposed and developed to remove the mask pattern from areas on the conductive layers 104, 106 that are to be etched away. It is understood the resulting mask pattern 120 may cover all of the plated areas 114, some of the plated areas 114 or none of the plated areas 114.

The areas of the conductive layers 104 and 106 that are exposed (i.e., not covered by mask pattern 120 or plating 114) are next etched away using an etchant in step 226 to define the conductance and dummy patterns on the core 102 as shown in FIG. 9. Where the plated areas 114 are covered by mask pattern 120, the etchant removes all areas not covered by the mask pattern 120. Where the plated areas 114 are not covered or only partially covered by mask pattern 120, the etchant removes all areas not covered by either the mask pattern 120 or the plated areas 114. If there are plated areas 114 that are not covered by the mask pattern 120, the etchant does not remove these plated areas. The result is that all areas beneath either the mask pattern 120 or the plated areas 114 are left intact in conductive layers 104 and 106. These intact areas include the plated electrical traces and contact pads.

Next, the photoresist is removed in step 230. The result is the pattern shown in the top view of FIG. 10 and the cross-sectional side view of FIG. 11. As shown in FIGS. 10 and 11, the above-described processes form substrate 100 with plated vias 108, plated electrical traces 122, plated contact pads 124, plated contact fingers 126, dummy patterns 128 and dummy plating areas 130. As used herein, the term “electrical connector” may be used to refer to the vias, traces and/or contact pads (either collectively or one or more of them), either with or without the plating layer. The electrical connectors define at least part of an electric circuit on (and through) the substrate. While the dummy pattern is formed in the conductive layer 104 and/or 106, it does not form part of the electric circuit defined by the electrical connectors.

As indicated in the Background of the Invention section, conventional double imaging processes resulted in peaks at the plated traces and vias, and valleys between the plated traces and vias. These peaks and valleys left an uneven surface in the finished substrate which generated mechanical stresses within the die affixed to the substrate. However, in accordance with the present invention, the plating material 114 is applied not only over the vias 108 and traces 122, but also within the dummy plating areas 130 in the dummy patterns 128 in between the vias 108 and traces 122. The plating 114 in the dummy plating areas 130 serves to increase the amount of plating on the surface(s) of the substrate 100, thereby lessening the space between adjacent plated areas found in conventional substrates such as that shown in prior art FIG. 2. The plated vias and/or traces and the plating within the dummy plating areas provide a plating pattern which is evenly distributed across the surface of the substrate 100. The even distribution of the plating pattern prevents peaks and valleys in the finished substrate.

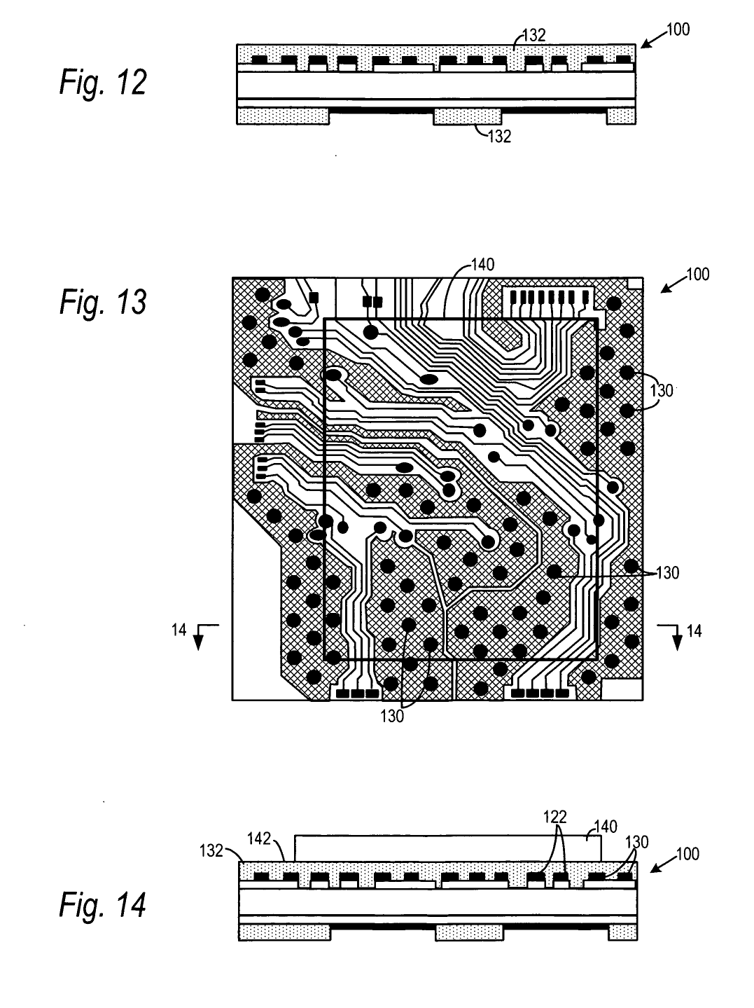

Once the double imaging process as described above is completed, the top and bottom surfaces of substrate 100 may be laminated with a solder mask 132 in a known step 234 to provide the structure shown in FIG. 12. Solder mask 132 may cover all areas except contact pads 124 and contact fingers 126. Again, as the plating pattern is distributed across the surface of the substrate, the solder mask 132 may provide flat or relatively flat surfaces without the peaks and valleys found in the prior art.

In a step 236 one or more die 140 may be mounted to a surface 142 of substrate 100 as shown in FIGS. 13 and 14 (the die 140 are shown in outline in FIG. 14). The die 140 may be electrically connected to substrate 100 by soldering leads (wire or leadframe fingers—not shown) of the die to contact pads 124 in a known wire bond and/or SMT mounting process. The die 140 may be any of a variety of semiconductor chips, such as for example flash memory chips (NOR/NAND), SRAM or DDT, and/or a controller chip such as an ASIC. However, the configuration of die 140 is not critical to the present invention and other semiconductor chips are contemplated. In addition to leadframe-based die 140, other electronic components may be surface mounted to substrate 100 in step 236 in embodiments of the present invention.

The dummy plating pattern 130 may be applied to the surface 142 of the substrate 100 that receives the die 140. Again, as shown in the cross-sectional view of FIG. 14, the even distribution of the plating pattern across the substrate 100 makes for a flat or relatively flat surface of the substrate 100. Thus, the one or more die 140 lie flat against the substrate 100 to reduce or remove the mechanical stresses generated on the die in prior art structures.

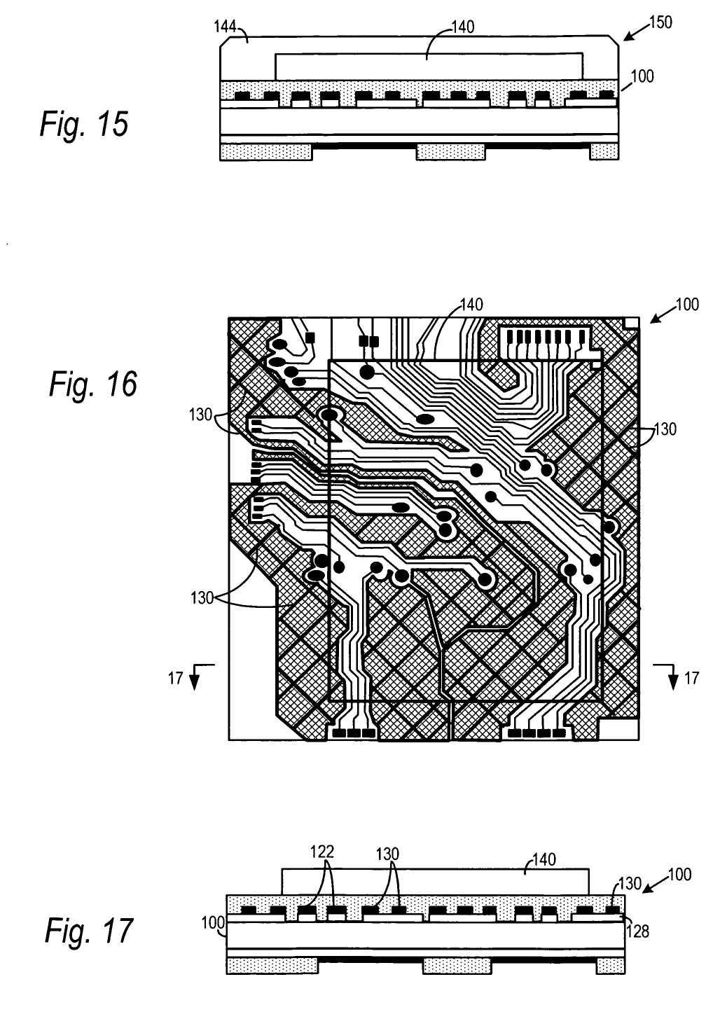

In step 238, the die 140 and at least the adjacent surface of the substrate 100 may be encapsulated in a molding compound 144 as shown in FIG. 15 to form a finished semiconductor package 150. The package 150 may be an SiP package used in any of a variety of applications, including for example as a flash memory device manufactured by SanDisk Corporation of Sunnyvale, Calif. Such a flash memory device may for example be an SD Card, a Compact Flash, a Smart Media, a Mini SD Card, an MMC, an xD Card, a combination SD-USB card, a Transflash or a Memory Stick. It is understood that the package 150 may be used in a variety of other semiconductor device applications.

The dummy plating areas 130 shown in FIGS. 10 and 13 described above include plating 114 applied in discrete and separate circular shapes. However, the dummy plating areas 130 may include a wide variety of patterns of plating material 114 in alternative embodiments. For example the plating material 114 may be applied in discrete and separate shapes, but may have a variety of curvilinear, rectilinear and irregular shapes in alternative embodiments. The size of such shapes may vary from 50 microns to about a millimeter, though the size of such shapes may be smaller or larger than that in alternative embodiments. The shapes of the plating 114 in dummy plating areas 130 may be filled and solid as shown, or the centers of the shapes may be open and free of plating material 114.

A still further embodiment of the plating 114 in dummy plating areas 130 is shown in FIGS. 16 and 17. As seen in the top view of FIG. 16, instead of discrete shapes, the plating in the dummy plating areas 130 may be applied as a plurality of segments having straight, curved and/or irregular shaped lengths. The plating material 114 of dummy plating areas 130 in this embodiment may be applied along the outline of dummy patterns 128. Alternatively or additionally, the plating material 114 of dummy plating areas 130 may be applied over the interior metal portions of the dummy patterns 128. For example, in FIG. 16, the dummy pattern 128 has a mesh pattern. Accordingly, the plating material 114 may be applied in a mesh pattern over the metal portions. The mesh pattern of the plating material 114 may exactly match the mesh pattern of the dummy pattern 128. Alternatively, the plating 114 may be applied over only a portion of the metal in the dummy pattern 128 (as shown in FIG. 16).

The configuration of the plating material 114 described above with respect to FIG. 16, together with the plated traces and/or vias, may provide a distributed plating pattern across the substrate 100 as described above and as shown in the cross-sectional side view of FIG. 17.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A substrate, comprising:
electrical connectors forming at least part of an electrical circuit on the substrate, the electrical connectors including a first layer of metal and a second layer of metal plated on the first layer; and
dummy plating areas adjacent the electrical connectors, the dummy plating areas including a first layer of metal not used in the electrical circuit, and a second layer of metal plated on the first layer.

2. A substrate as recited in claim 1, further comprising solder mask covering at least portions of the electrical connectors and dummy plating areas, the second layer of metal of the electrical connectors and the second layer of metal in the dummy plating areas together providing a flat surface of the solder mask.

3. A substrate as recited in claim 1, wherein the first metal layer of the electrical connectors and the first metal layer of the dummy plating area are defined in a common layer of conductive material on the substrate.

4. A substrate as recited in claim 1, wherein the second metal layer of the electrical connectors and the second metal layer of the dummy plating area are plated on the substrate in the same process.

5. A substrate as recited in claim 1, wherein the second metal layer of the dummy plating area is provided to fill spaces on the substrate adjacent to the second metal layer of the electrical connectors.

6. A substrate as recited in claim 1, wherein the second metal layer of the dummy plating area is formed of nickel and gold.

7. A substrate, comprising:
a conductive layer having electrical traces defined in the conductive layer; and
a distributed plating pattern including:
a first amount of plating material deposited onto the conductive layer over the electrical traces, and
a second amount of plating material, deposited on the conductive layer, for filling in spaces on the substrate adjacent to the first amount of plating material.

8. A substrate as recited in claim 7, wherein the second amount of plating material is deposited in a substantially uniform distributed pattern on the conductive layer in areas not occupied by the electrical traces.

9. A substrate as recited in claim 7, wherein the second amount of plating material is deposited on the conductive layer in a plurality of discrete circular shapes.

10. A substrate as recited in claim 7, wherein the second amount of plating material is deposited on the conductive layer in a plurality of discrete shapes.

11. A substrate as recited in claim 7, wherein the second amount of plating material is deposited on the conductive layer in a plurality of segments having a straight, curvilinear or irregular shape lengths.

12. A substrate as recited in claim 7, further comprising a dummy pattern defined in the conductive layer, the second amount of plating material being deposited on the dummy pattern.

13. A substrate as recited in claim 12, wherein the second amount of plating material is deposited in a substantially uniform distributed pattern on the dummy pattern.

14. A substrate as recited in claim 12, wherein the second amount of plating material is deposited on the conductive layer in a plurality of segments overlying at least portions of the dummy pattern.

15. A substrate including a conductive surface, comprising:
a conductance pattern defined in the conductive surface, the conductance pattern including electrical connectors for carrying electrical signals;
a dummy pattern defined in the conductive surface in areas not occupied by the conductance pattern; and
plating material plated onto the conductive surface over at least a portion of the conductance pattern and over at least a portion of the dummy pattern.

16. A substrate as recited in claim 15, further comprising solder mask over at least portions of the conductance pattern, dummy pattern and plating material.

17. A substrate as recited in claim 16, wherein the plating material provides the solder mask with at least a substantially flat surface.

18. A substrate as recited in claim 15, wherein the plating material plated over at least a portion of the dummy pattern is plated in a distributed pattern of a plurality of discrete shapes.

19. A substrate as recited in claim 15, wherein the plating material plated over at least a portion of the dummy pattern is plated in a plurality of discrete circular shapes.

20. A substrate as recited in claim 15, wherein the plating material plated over at least a portion of the dummy pattern is plated in a plurality of discrete shapes.

21. A substrate as recited in claim 15, wherein the plating material plated over at least a portion of the dummy pattern is plated in a plurality of segments having straight, curvilinear or irregular shape lengths.

22. A substrate as recited in claim 21, wherein the plurality of segments overlie an outline of the dummy pattern.

23. A substrate as recited in claim 21, wherein the plurality of segments overlie at least a portion of the pattern of the dummy pattern.

24. A substrate, comprising:
a conductive layer on a surface of the substrate, the conductive layer including:
electrical traces defined in the conductive layer, and
a dummy pattern defined in the conductive layer adjacent the electrical traces;
a first amount of plating material deposited on the conductive layer over the electrical traces;
a second amount of plating material deposited onto the conductive layer over at least portions of the dummy pattern;
solder mask deposited on at least portions of the conductive layer, the first amount of plating material and the second amount of plating material;
wherein the second amount of plating material is deposited for improving a flatness of a surface of the solder mask.

25. A substrate as recited in claim 24, wherein the second amount of plating material deposited onto the conductive layer over at least portions of the dummy pattern is deposited in a distributed pattern of a plurality of discrete shapes.

26. A substrate as recited in claim 24, wherein the second amount of plating material deposited onto the conductive layer over at least portions of the dummy pattern is deposited in a plurality of segments having straight, curvilinear or irregular shape lengths.

27. A semiconductor package, comprising:
a substrate, including:
a conductive layer on a surface of the substrate, the conductive layer including:
electrical traces defined in the conductive layer, and
a dummy pattern defined in the conductive layer adjacent the electrical traces,
a first amount of plating material deposited on the conductive layer over the electrical traces,
a second amount of plating material deposited onto the conductive layer over at least portions of the dummy pattern,
solder mask deposited on at least portions of the conductive layer, the first amount of plating material and the second amount of plating material; and
one or more semiconductor die affixed to a surface of the solder mask;
wherein the second amount of plating material is deposited for improving a flatness of the surface of the solder mask on which the semiconductor die is affixed.

28. A semiconductor package as recited in claim 27, wherein the first and second amounts of plating material are deposited onto the conductive layer in the same process.

29. A semiconductor package as recited in claim 27, wherein the second amount of plating material deposited onto the conductive layer over at least portions of the dummy pattern is deposited in a distributed pattern of a plurality of discrete shapes.

30. A semiconductor package as recited in claim 27, wherein the second amount of plating material deposited onto the conductive layer over at least portions of the dummy pattern is deposited in a plurality of segments having straight, curvilinear or irregular shape lengths.

31. A semiconductor package as recited in claim 27, wherein the first and second amounts of plating material are formed of nickel and gold.
